(19) United States
(12) Patent Application Publication
(10) Pub. No.: US 2023/0065356 A1
(43) Pub. Date: Mar. 2, 2023

(54) Simplified Structure for a Low Gain Avalanche Diode with Closely Spaced Electrodes

(71) Applicant: Brookhaven Science Associates, LLC, Upton, NY (US)

(72) Inventor: Gabriele Giacomini, Ridge, NY (US)

(21) Appl. No.: 17/462,363

(22) Filed: Aug. 31, 2021

(51) Int. Cl. H01L 29/66; H01L 31/107; H01L 27/146; H01L 29/868

(52) U.S. Cl. CPC H01L 29/66113; H01L 31/107; H01L 27/14643; H01L 29/868

(57) ABSTRACT

A method for fabricating a low-gain avalanche diode (LGAD) device is provided. The method includes: forming a low-resistivity n-type semiconductor substrate in a first silicon wafer; forming a p-type gain layer in an upper surface of a high-resistivity p-type second silicon wafer; bonding the first and second wafers such that the upper surface of the second wafer proximate the gain layer contacts the semiconductor substrate in the first wafer to form a bonded wafer structure, whereby a back surface of the second wafer becomes an upper surface of the bonded wafer structure; forming a plurality of p-type electrodes in the upper surface of the bonded wafer structure; and forming a conductive layer on at least a portion of the respective p-type electrodes and on a back surface of the semiconductor substrate, the conductive layer providing electrical connection to the LGAD device.

This application claims priority from U.S. provisional patent application Ser. No. 63/073,007, filed on Sep. 1, 2020.

This invention was made with Government support under contract number DE-SC0012704, awarded by the U.S. Department of Energy. The Government has certain rights in the invention.

### BACKGROUND

The present invention relates generally to the electrical, electronic and computer arts, and, more particularly, to low-gain avalanche diodes and fabrication methods.

Silicon-based radiation detectors based on a PIN diode are well known and are used to detect high-energy particles. The PIN diode, when operated with an externally supplied reverse bias in full or partial depletion, generates a signal that is proportional to the energy deposited by the incident radiation. In order to detect low energy particles, an avalanche photodiode detector (APD) was developed. This type of detector exhibits an internal signal gain that is a strong function of the applied bias voltage. When operated in a linear region, the APD device generates a signal that is still proportional to the absorbed energy, but with a gain factor usually above 100. However, there is significant noise (“jitter”) associated with the multiplication process that can lead to a low signal-to-noise ratio (SNR), which is undesirable. Furthermore, leakage current often associated with APD devices are often unacceptably high for use in most detector applications.

Low-gain avalanche diodes (LGADs) are a class of silicon sensors that have attracted attention, especially in low energy or fast charged particle detection applications, in part due to their fast-timing properties and low-noise. A disadvantage of conventional LGADs and APDs as well, however, is that they generally do not allow for fine patterning of electrodes (n+ electrodes are spaced at least about 1 millimeter (mm) apart); attempts to design n+ electrodes having closer spacing results in a loss of active area (i.e., fill factor).

### SUMMARY

The present invention, as manifested in one or more embodiments, beneficially provides a simplified structure for a low-gain avalanche diode (LGAD) device having closely spaced electrodes configured to provide fine-pixel low-energy signal detection.

In accordance with an embodiment of the invention, a method for fabricating an LGAD device is provided. The method includes: forming a low-resistivity n-type semiconductor substrate in a first silicon wafer; forming a p-type gain layer in an upper surface of a high-resistivity p-type second silicon wafer; bonding the first and second wafers such that the upper surface of the second wafer proximate the gain layer contacts the semiconductor substrate in the first wafer to form a bonded wafer structure, whereby a back surface of the second wafer becomes an upper surface of the bonded wafer structure; forming a plurality of p-type electrodes in the upper surface of the bonded wafer structure; and forming a conductive layer on at least a portion of the respective p-type electrodes and on a back surface of the semiconductor substrate, the conductive layer providing electrical connection to the LGAD device.

In accordance with another embodiment of the invention, a method for fabricating an LGAD device which eliminates the need for wafer bonding is provided. The method includes: obtaining a silicon wafer including a low-resistivity n-type semiconductor substrate; forming a first epitaxial layer on at least a portion of an upper surface of the semiconductor substrate, the first epitaxial layer being of n-type or p-type conductivity; forming a p-type gain layer in an upper surface of the first epitaxial layer, the gain layer being closely proximate the upper surface of the semiconductor substrate; forming a second epitaxial layer on at least a portion of an upper surface of the first epitaxial layer and over the gain layer, the second epitaxial layer being p-type and having a cross-sectional thickness that is configured to achieve a prescribed speed performance in the LGAD device; forming a plurality of p-type electrodes in an upper surface of the second p-type epitaxial layer; and forming a conductive layer on at least a portion of the respective p-type electrodes and on a back surface of the semiconductor substrate, the conductive layer providing electrical connection to the LGAD device.

Techniques of the present invention can provide substantial beneficial technical effects. By way of example only and without limitation, an LGAD device formed according to one or more embodiments of the invention may provide one or more of the following advantages:
a simplified LGAD device structure and fabrication method;
a gain layer that is formed deeper in the LGAD device, proximate a junction between the n-type substrate and p-type epitaxial layer and away from electrodes of the device, to achieve uniform gain;
provides the ability to form closely-spaced segmented electrodes in the LGAD device to thereby achieve fine-pixel low-energy signal detection;
compatible with standard CMOS monolithic fabrication for easily integrating the LGAD device with other CMOS devices and circuits.

These and other features and advantages of the present invention will become apparent from the following detailed description of illustrative embodiments thereof, which is to be read in connection with the accompanying drawings.

### BRIEF DESCRIPTION OF THE SEVERAL VIEWS OF THE DRAWINGS

Non-limiting and non-exhaustive embodiments of the present invention will be described with reference to the following drawings which are presented by way of example only, wherein like reference numerals (when used) indicate corresponding elements throughout the several views unless otherwise specified, and wherein:

FIG. 1 is a cross-sectional view depicting an illustrative standard low-gain avalanche diode (LGAD) device;

FIG. 2 is a cross-section view depicting an illustrative standard AC-coupled LGAD device;

FIG. 3 is a cross-sectional view depicting at least a portion of an exemplary LGAD device that achieves superior performance and employs a substantially simplified fabrication process, according to an embodiment of the present invention;

FIGS. 4A through 4C are cross-sectional views depicting at least a portion of exemplary processing steps in the fabrication of an exemplary LGAD device consistent with the illustrative LGAD device shown in FIG. 3, according to an embodiment of the present invention;

FIG. 5 is a cross-sectional view depicting at least a portion of the exemplary LGAD device shown in FIG. 4C including optional termination structures for reducing high current flow in the device, according to an embodiment of the present invention;

FIG. 6 is a cross-sectional view depicting at least a portion of an exemplary LGAD device that achieves superior performance and employs a substantially simplified fabrication process, according to an alternative embodiment of the present invention;

FIG. 7 is a cross-sectional view depicting at least a portion of an exemplary monolithic CMOS structure for integrating an LGAD device according to embodiments of the present invention with other CMOS devices and circuitry;

FIG. 8 is a flow diagram depicting at least a portion of an exemplary method for fabricating an LGAD device, according to an embodiment of the present invention; and

FIG. 9 is a flow diagram depicting at least a portion of an exemplary method for fabricating an LGAD device without a need for wafer bonding, according to another embodiment of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of the present invention, as manifested in one or more embodiments, will be described herein in the context of illustrative low-gain avalanche diode (LGAD) devices having closely spaced electrodes for achieving superior spatial resolution without compromising speed performance, and fabrication methods for forming such LGAD devices. It is to be appreciated, however, that the invention is not limited to the specific device(s) and/or fabrication method(s) illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

Although the overall fabrication methods and structures formed thereby are entirely novel, certain individual processing steps required to implement a portion or portions of the method(s) according to one or more embodiments of the invention may utilize conventional semiconductor fabrication techniques and conventional semiconductor fabrication tooling. These techniques and tooling will already be familiar to one having ordinary skill in the relevant arts. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; R. K. Willardson et al., Processing and Properties of Compound Semiconductors, Academic Press, 2001; and Simon M. Sze et al., Semiconductor Devices: Physics and Technology, 3^{rd} Edition, Wiley, 2012, which are incorporated by reference herein in their entireties. It is emphasized that while some individual processing steps are set forth herein, those steps are merely illustrative and one skilled in the art may be familiar with several equally suitable alternatives that would also fall within the scope of the present invention.

It is to be understood that the various layers and/or regions shown in the accompanying figures are not necessarily drawn to scale. Furthermore, one or more semiconductor layers of a type commonly used in such integrated circuit devices may not be explicitly shown in a given figure for economy of description. This does not imply, however, that the semiconductor layer(s) not explicitly shown are omitted in the actual integrated circuit device.

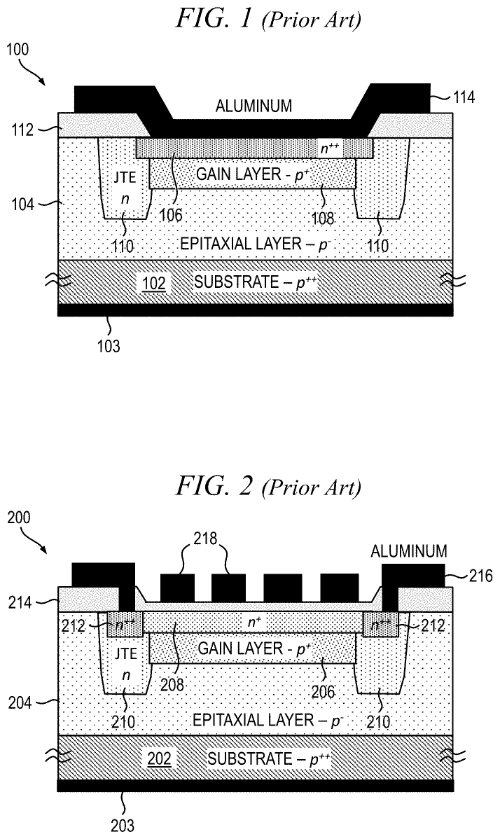

LGAD devices enable the detection of sub-nanosecond signals produced by minimum ionizing particles, where the ionization is produced uniformly as a function of depth in the detector (but also X-rays produced in the active layers are detected and amplified). FIG. 1 is a cross-sectional view depicting an illustrative standard LGAD device 100. The LGAD device 100 includes a thick (e.g., about 300 μm) low-resistivity silicon p-type (p⁺⁺) substrate 102. A p⁺ anode with metal 103 providing electrical connection to the substrate 102 is formed on a back surface of the substrate. An active volume of the LGAD device 100 is a p-type epitaxial layer 104, or a thin silicon layer wafer-bonded to the thick substrate 102 that acts as a mechanical support structure. The epitaxial layer 104 is formed on an upper surface of the substrate 102, for example using a standard epitaxial growth process. The thickness of the epitaxial layer 104 can be a few tens of microns in order to have a short drift of charge carriers.

An n⁺⁺ implant layer 106 creates a p-n junction with the p-type substrate 102, in a manner consistent with the formation of standard diode. Additionally, a p-type gain (or multiplication) layer 108 is formed partially in the epitaxial layer 104 proximate an upper surface of the epitaxial layer, just below the n⁺ implant layer 106. Application of an external bias to the junction leads to depletion of this gain layer 108, which results in a high electric field being formed in a superficial region that extends in depth for about one micron. Electron impact ionization is generated by this high electric field when the drifting electrons enter the gain layer volume, while the ionization rate of the holes is at a negligible level.

LGAD detectors have a region with a high electrical field to cause multiplication of signal charges (electron and/or holes) flowing through this region. The result is an amplified current pulse that is dominated by the motion of holes through the whole thickness of the epitaxial layer 104. These current pulses, amplified by a factor typically in the range of 10-100, are inherently fast and can offset the limited amount of charge released by a minimum ionizing particle (MIP) in the epitaxial layer 104. This gain mechanism is achieved within the semiconductor material by raising the electric field as high as necessary to enable the drifting electrons to create secondary ionization during the collection process. Keeping the gain value at a moderate level (i.e., considerably below the avalanche regime) is instrumental in keeping the noise low.

For a stable and reproducible amplification, electric field lines inside the LGAD device 100, when depleted, are desirably straight and parallel to each other. To achieve this objective, edge effects are minimized by designing pads with sizes far larger than the silicon active thickness. At the edges of the n⁺⁺ implant layer 106, an additional deep n implant may be inserted to surround and protect the device from early breakdown. This is usually called a junction termination edge (JTE). In the LGAD device 100, JTE implant structures 110 are formed at both ends of the n⁺⁺ implant layer 106, as shown in the cross-sectional view of FIG. 1; in the actual three-dimensional device, the JTE implant structures surround the n⁺⁺ implant layer 106. To keep the dead area small at the edges of the device, the JTE structures 110 are made as narrow as practical.

An oxide or other insulating layer 112 is formed over at least a portion of an upper surface of the LGAD device 100. An opening is then formed through the oxide layer 112 to expose the n⁺⁺ implant layer 106. A cathode electrode 114 is formed through the opening in the oxide layer 112 and provides electrical connection with the underlying n⁺⁺ implant layer 106. The advantages of this LGAD device 100 are the fast and boosted signals that are due to (i) the thin active silicon epitaxial layer 104, and (ii) the gain layer 108 that amplifies the initial charge generated by the ionizing event by a factor of a few tens.

A disadvantage with the standard LGAD device (e.g., LGAD device 100 in FIG. 1), however, is that it does not allow for the n⁺⁺ cathode electrode 114 to be finely patterned while maintaining fast signals. Typically, the n⁺⁺ electrodes in a standard LGAD device are spaced about 1 mm apart. Standard LGAD devices are substantially larger than the substrate thickness in order to achieve uniform gain and a sufficient fill factor (i.e., the dead or inactive device area should be a small percentage of the total device area). Attempts at designing more closely spaced electrodes may result in a loss of active area (fill factor) in a standard LGAD device. For example, an LGAD device having a substrate of about 20 μm-50 μm will require an area on the order of about 1 mm².

FIG. 2 is a cross-sectional view depicting an illustrative AC-coupled LGAD device 200. Like the standard LGAD device 100 shown in FIG. 1, the AC-coupled LGAD device 200 comprises a thick (e.g., about 300 μm) low-resistivity silicon p-type (p⁺⁺) substrate 202. A p⁺⁺ anode electrode with metal 203 providing electrical connection to the substrate 202 is formed on a back surface of the substrate. The AC-coupled LGAD device 200 further includes a p-type epitaxial layer 204 which forms an active volume of the device. The epitaxial layer 204 is formed on an upper surface of the substrate 202, for example using a standard epitaxial growth process. The thickness of the epitaxial layer 204 can be a few tens of microns in order to have a short drift of charge carriers.

A p-type gain (or multiplication) layer 206 is formed partially in the epitaxial layer 204 proximate an upper surface of the epitaxial layer. One of the differences between the AC-coupled LGAD device 200 and the standard LGAD device 100 is the replacement in the AC-coupled LGAD device 200 of the n⁺⁺ implant layer (106 in FIG. 1) by a much less doped n⁺ implant layer 208 formed on an upper surface of the gain layer 206. The n⁺ implant layer 208 creates a p-n junction with the p⁺⁺ substrate 202, in a manner consistent with the formation of standard diode. Additionally, JTE implant structures 210 may be formed at both ends of the n⁺ implant layer 208, when viewed in two-dimensional cross-section; in the actual three-dimensional device, the JTE implant structure surrounds the gain layer 206 and implant layer 208. Highly-doped n-type (n⁺⁺) implant regions 212 are formed in an upper surface of the JTE implant structures 210. These n⁺⁺ implant regions 212 provide enhanced electrical connection between a cathode electrode and the n⁺ implant layer 208.

Similar to the standard LGAD device 100 of FIG. 1, an oxide or other insulating layer 214 is formed over at least a portion of an upper surface of the AC-coupled LGAD device 200. Openings are then formed through the oxide layer 214 to expose the underlying n⁺⁺ implant regions 212. Connections 216 are formed through the openings in the oxide layer 214 electrically contacting the underlying n⁺⁺ implant layer 212, which is in contact with the n⁺ layer 208. These connections 216 are DC-connected to a voltage source for electron current draining.

At least a portion of the oxide layer 214 above the n⁺ implant layer 208 may be thinned to form an AC coupling oxide layer proximate the n⁺ implant layer. In the AC-coupled LGAD device 200, electrodes, to which the read-out electronics are connected, are formed as a plurality of metal pads 218 on an upper surface of the oxide layer 214 above the n⁺ implant layer 208. Since AC-coupled electrodes do not collect charge, the current induced on the metal pads 218 is bipolar with zero net integral, with a first peak accounting for the drift of the multiplication holes into the epitaxial layer 204, and a second peak of opposite polarity, to account for diffusion of the electrons within the n⁺ implant layer 208 towards the n⁺⁺ implant regions 212 at the edge of the device 200.

Since the n⁺ implant layer 208 is continuous, the metal pads 218 over the oxide layer 214 experience a low inter-pad resistance Rₙ, and this can cause two effects. First, a potentially large thermal Johnson noise component can be fed into the front-end electronics. Second, signal loss occurs if Rₙ<<(ωC_{AC})⁻¹, where C_{AC} is the effective capacitance of the metal pad towards the n⁺ implant layer 208. Furthermore, in the AC-coupled LGAD device 200, the signal is bipolar so that it needs to be read-out with very fast electronics; using slower electronics, which would otherwise be possible for a standard LGAD device, is not possible in this case. Fast electronics with a large number of channels may not be available. Moreover, there are limitations on the values of the coupling capacitances and resistances that can be achieved in a silicon process, which can set a lower limit to the pixilation.

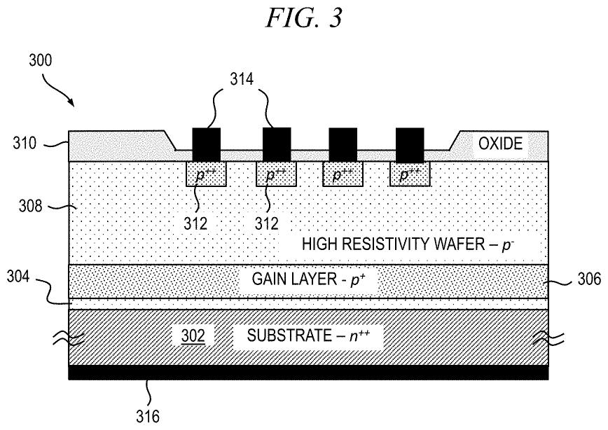

FIG. 3 is a cross-sectional view depicting at least a portion of an exemplary LGAD device 300 that achieves superior performance and employs a substantially simplified fabrication process, according to an embodiment of the invention. With reference to FIG. 3, the simplified LGAD device 300 includes a low-resistivity handling substrate 302 having n-type (n⁺⁺) conductivity, which may be a few hundreds of microns thick (but can be thinned down as desired, for example a range of about a minimum thickness of a few nanometers to about a few hundred microns thick or other maximum desired thickness for the substrate in the wafer), on which a layer of intrinsic or p-type conductivity high-resistivity silicon 304 is grown. The substrate 302, in one or more embodiments, is formed of monocrystalline silicon (e.g., having a <100>, <111>, or other crystal orientations) that is modified by adding an n-type impurity or dopant (e.g., Group V elements, such as phosphorous or arsenic) of a prescribed concentration level (e.g., about 10¹⁴ to 10¹⁸ atoms per cubic centimeter (cm⁻³)) to the substrate material during the crystal growth process. The resistivity of the n⁺⁺ substrate 302 is preferably below about 0.1 ohm-cm, although embodiments of the invention are not limited to any specific resistivity of the substrate.

Similarly, the high-resistivity silicon layer 304 can be formed of silicon that has been modified by adding a p-type dopant (e.g., Group III elements, such as boron) of a prescribed concentration level (e.g., below about 10¹⁴ atoms per cubic centimeter) to the silicon layer material, to change the conductivity of the material as desired. In one or more embodiments, the resistivity of the p⁻ silicon layer 304 is at least 100 ohm-cm (i.e., above about 100 ohm-cm) although embodiments of the invention are not limited to any specific resistivity of the silicon layer. An epitaxial growth process may be used to form the high-resistivity silicon layer 304. A thickness of the high-resistivity silicon layer 304 is preferably about 1-2 μm, although embodiments of the invention are not limited to this specific thickness.

A p-type (p⁺) conductivity gain layer 306 is formed on an upper surface of the high-resistivity silicon layer 304. The gain layer 306 may be formed using a blank (i.e., without pattern) p-type implant (e.g., boron ion implantation, etc.) having a prescribed doping concentration (e.g., 10¹⁶ cm⁻³ to 10¹⁷ cm⁻³). In one or more embodiments, the gain layer 306 can also be patterned. Alternatively, the epitaxial layer itself may be used as the gain layer 306. Depending on certain thicknesses, concentration of dopants or other parameters the epitaxial layer may show some gain. In this case, the resistivity of the epitaxial layer is not as high, compared to the high-resistivity layer 304, and there is no need to use the blank p-type implant (i.e., perform the implant step.) A gain of the gain layer 306, which will be a function of a distance between the p-type gain layer and an n-type electrode overlying the gain layer as well as its doping concentration, is preferably about 10-100.

A second p-type high-resistivity epitaxial layer 308 is then formed (e.g., deposited, grown, etc.) on an upper surface of the gain layer 306. The second epitaxial layer 308, in one or more embodiments, is formed having a thickness of about 50 μm. This distance provides sufficient spacing between the gain layer 306 and device electrodes (on an upper surface of the device 300), so as to provide uniform gain. For a substantially uniform gain, a depth of the junction between the n-type substrate and the p-type gain layer should be much greater (e.g., a factor of 3) than a gap between electrodes.

An insulating or dielectric layer 310, which in one or more embodiments is an oxide (e.g., silicon dioxide), is formed on an upper surface of the second epitaxial layer 308. An opening is formed through the insulating layer 310 to expose the upper surface of the second epitaxial layer 308. A plurality of p-type conductivity implants (p⁺⁺) 312 are formed in the upper surface of the second epitaxial layer 308, through the opening in the insulating layer 310. These p⁺⁺ implants 312, which may be formed, for example, using boron at a doping concentration on the order of greater than about 10¹⁸ cm⁻³, serve as pixelated electrodes of the LGAD device. On each of the respective p⁺⁺ implants 312 are formed electrical contacts 314. The contacts 314, in one or more embodiments, are formed of a metal, such as, for example, aluminum. A conductive layer 316 (e.g., aluminum) is formed on a back surface of the substrate 402 for providing electrical connection to the substrate.

X-rays or other charged particles create electron/hole pairs inside the 50-μm thick second epitaxial layer 308. Holes are promptly collected by the p⁺⁺ electrodes 312 located on the upper surface of the second epitaxial layer 308. Electrons drift to the n⁺⁺ substrate 302 and, by crossing a high electric field region between the gain layer 306 and the substrate 302, get amplified. Multiplied holes drift back to the p⁺⁺ electrodes 312, generating the majority of the signal. Signals are similar to the LGAD case, but fine pixilation, provided by the p⁺⁺ electrodes 312 proximate the upper surface of the device 300, is advantageously possible.

The illustrative LGAD devices (100 and 200) shown in FIGS. 1 and 2 utilize p-type substrates, which is in contrast to the n-type substrate 302 in the simplified LGAD device 300 according to embodiments of the present invention. The use of an n-type substrate allows the gain layer in the device to be shifted further away from the patterned electrodes, thereby achieving uniform gain in the present device. This device arrangement exploits a property of silicon wherein the ionization coefficients for electrons are higher than that for holes. Electrons, that are collected by the n⁺⁺ substrate (serving as an electrode) 302 in the LGAD device 300, pass through a high (and uniform—as determined by measuring the gain as a function of the hit position of the particle) electric field. The high electric field is in reference to the thickness of the p-type substrate. This electric field is generated by a uniform (and large) p-n junction in the device. The n component of the p-n junction, in this embodiment, is the wafer (n⁺⁺ substrate) itself. The multiplied holes generated as a result of the ionization process then drift to the patterned p⁺⁺ electrodes 312.

Furthermore, comparing the illustrative LGAD devices 100, 200 and 300, the gain layer 306 in the exemplary LGAD device 300 shown in FIG. 3 is formed at a significantly greater depth into the epitaxial layer (308) relative to the other LGAD devices 100 and 200 depicted in FIGS. 1 and 2, respectively; the LGAD device 300 having a gain layer that is proximate an interface between the n⁺⁺ substrate 302 and the p⁻ epitaxial layer 304, and the LGAD devices 100, 200 having a gain layer that is closer to the upper surface of the epitaxial layer. Having the gain layer reside close to the interface between the handling substrate and the active silicon region (i.e., epitaxial layer), rather than being located near the upper surface of the epitaxial layer, allows for a more uniform gain. In order to achieve uniform gain, the junction depth should be much greater than electrode gap in the device (e.g., a factor of 3).

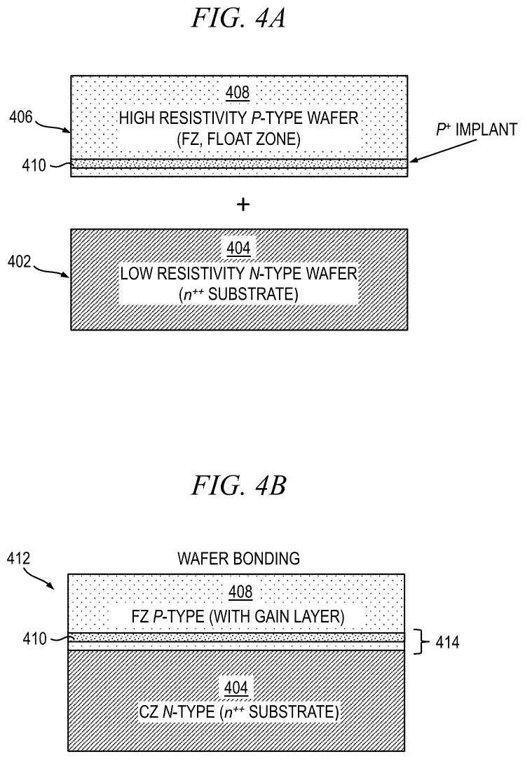

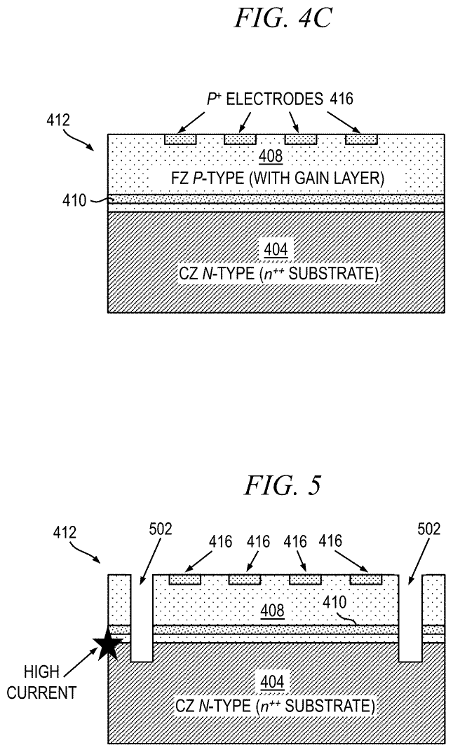

FIGS. 4A through 4C are cross-sectional views depicting at least a portion of exemplary processing steps in the fabrication of an exemplary LGAD device consistent with the illustrative LGAD device 300 shown in FIG. 3, according to an embodiment of the invention. With reference to FIG. 4A, the exemplary fabrication process starts with a first wafer 402 comprising a low-resistivity n-type substrate 404. The first wafer can be a Czochralski (CZ) or Float Zone (FZ) wafer. The resistivity of the substrate 404, in one or more embodiments, is preferably less than about 0.1 ohm-cm, although the invention is not limited to any specific resistivity for the substrate. A second wafer 406 comprises a high-resistivity p-type material layer 408, preferably an FZ wafer, in which a p-type implant (p⁺) layer 410 is formed proximate an upper surface of the second wafer. In one or more embodiments, the p⁺ implant layer 410 comprises boron formed using standard ion implantation. The p⁺ implant layer 410 will form a gain layer of the LGAD device.

In FIG. 4B, the second wafer (406 in FIG. 4A) is flipped over and bonded with the first wafer (402 in FIG. 4A) to form an LGAD bonded wafer structure 412. More particularly, the upper surface of the second wafer (406) is bonded to the upper surface of the first wafer (402), such that the p⁺ implant layer 410 is proximate to the n⁺⁺ substrate 404. To achieve fast timing properties (e.g., on the order of a few tens of picoseconds), the second wafer (top, FZ p-type wafer) is thinned down to a thickness of about 50 μm from its original thickness of about 300 μm. This thinning can be accomplished using, for example, grinding or polishing (chemical mechanical planarization (CMP)) of the back surface of the wafer. A high electric field will form in an interface region 414 between the first and second wafers. Due to the thickness of the second wafer, the distance between an upper surface of the bonded wafer structure 412 (i.e., the back surface of the second/top p-type wafer) and the high electric field region 414 is substantially large (e.g., about 50 μm after thinning), compared to a standard LGAD device, which utilizes a gain layer proximate the upper surface of the device as previously stated.

With reference to FIG. 4C, a plurality of p-type (p⁺⁺) electrodes 416 are formed in the upper surface of the bonded wafer structure 412. In one or more embodiments, the p⁺⁺ electrodes 416 are formed using an implant process, such as ion implantation. A contact metallization process is then employed to form conductive (e.g., metal) contacts with the respective electrodes 416 (e.g., 314 in FIG. 3) and at least one metal contact formed on a back surface of the substrate (e.g., 316 in FIG. 3) for providing electrical connection with the substrate. Thus, the process for fabricating the LGAD device according to embodiments of the invention involves only one ion implantation (for the p⁺⁺ electrodes 416)—or two if the gain layer 410 is considered—and three lithographies (p⁺⁺, contact and metal).

One phenomenon that may occur in the LGAD bonded wafer structure 412 is that at the edges of the device, where the n-type wafer is in contact with the p-type wafer, large currents may develop. Such large currents may enter an active area of the device and degrade or otherwise affect an operation of the device. In order to eliminate or at least reduce these large currents or high current flow from entering the active area of the device, termination structures may be optionally formed in the device.

FIG. 5 is a cross-sectional view depicting at least a portion of the exemplary LGAD device 412 including termination structures for reducing high current flow in an active area of the device, according to an embodiment of the invention. As shown in FIG. 5, the exemplary LGAD device 412 includes termination structures, which in this illustrative embodiment are formed as trenches 502 through the second wafer (i.e., through the high-resistivity p-type layer 408 and p⁺ gain layer 410) and partially into the first wafer (i.e., n⁺⁺ substrate 404). The trenches 502, when envisioned as a three-dimensional structure, surround the active LGAD device, as will become apparent to those skilled in the art given the teachings herein.

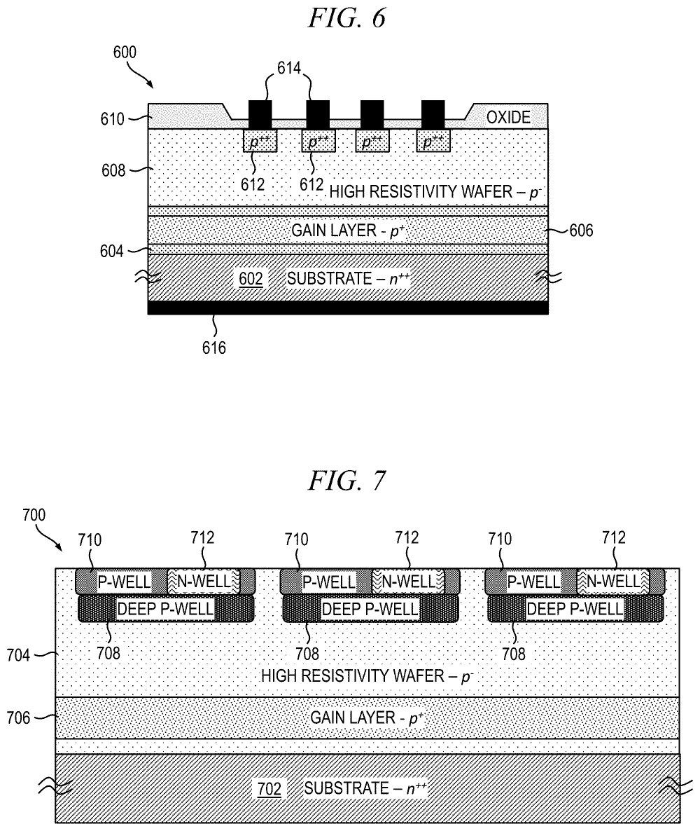

FIG. 6 is a cross-sectional view depicting at least a portion of an exemplary LGAD device 600 that achieves superior performance and employs a substantially simplified fabrication process, according to an alternative embodiment of the invention. With reference to FIG. 6, the LGAD device 600, like the illustrative LGAD device 300 shown in FIG. 3, includes a low-resistivity n-type (n⁺⁺) substrate (wafer) 602. The n⁺⁺ substrate 602, in one or more embodiments, is formed of mono-crystalline silicon that is modified by adding an n-type impurity or dopant (e.g., phosphorous or arsenic) of a prescribed concentration level (e.g., about 10¹⁴ to about 10¹⁸ cm⁻³) to the substrate material, during crystal growth, to change the conductivity of the material as desired. The resistivity of the substrate 602 is preferably below about 0.1 ohm-cm, although embodiments of the invention are not limited to any specific resistivity. The thickness of the substrate 602 is on the order of a few hundreds of microns, but it can be thinned down as desired for example a range of about a minimum thickness of a few nanometers, to about a few hundred microns thick or other maximum desired thickness for the substrate (wafer).

A high-resistivity n- or p-type epitaxial layer 604 is formed on an upper surface of the substrate 602, such as by using an epitaxial growth. A p-type gain layer 606 is then formed in the n- or p-type epitaxial layer 604, such as by an implant process (e.g., ion implantation or the like). A high-resistivity p-type layer 608 is formed on an upper surface of the n- or p-type epitaxial layer 604. In one or more embodiments, the high-resistivity p-type layer 608 is implemented as a high-resistivity p⁻ wafer bonded to the surface of the n- or p-type epitaxial layer 604. In alternative embodiments, the high-resistivity p-type layer 608 may be a p-type layer that is epitaxially grown over the n- or p-type epitaxial layer 604.

An insulating or dielectric layer 610, which in one or more embodiments is an oxide (e.g., silicon dioxide), is formed on an upper surface of the high-resistivity p-type layer 608. An opening is formed through the insulating layer 610 to expose the upper surface of the high-resistivity p-type layer 608. A plurality of p-type electrodes (p⁺⁺) 612 are formed in the upper surface of the high-resistivity p-type layer 608, through the opening in the insulating layer 610. The p⁺⁺ electrodes may be preferably formed or may be formed using an implant process (e.g., ion implantation). On each of the respective p⁺⁺ electrodes 612 are formed conductive contacts 614. The contacts 614, in one or more embodiments, are formed of a metal, such as, for example, aluminum. A conductive layer 616 (e.g., aluminum) may also be formed on a back surface of the substrate 602 for providing electrical connection to the substrate.

Aspects of the present invention are compatible with standard complementary metal-oxide-semiconductor (CMOS) fabrication for easily integrating the novel LGAD device with other CMOS devices and circuitry. FIG. 7 is a cross-sectional view depicting at least a portion of an exemplary monolithic CMOS structure 700 for integrating an LGAD device according to embodiments of the invention with other CMOS devices and/or circuitry. For monolithic CMOS LGAD device fabrication, the CMOS foundry begins with a wafer that comprises a low-resistivity n-type (n⁺) substrate 702 on which a high-resistivity p-type (p⁻) epitaxial layer 704 is formed (e.g., grown), or, alternatively, on which a high-resistivity p-type wafer is bonded. A p-type (p⁺) gain layer 706 is formed in the p⁻ epitaxial layer 704, for example using an implant process as previously described.

With continued reference to FIG. 7, the monolithic CMOS structure 700 includes a plurality of deep p-type wells (p-well) 708 formed at a prescribed depth in the high-resistivity p⁻ epitaxial layer 704 proximate an upper surface of the p⁻ epitaxial layer. These deep p-wells 708 serve as the p-type hole-collecting electrodes (e.g., p⁺ electrodes 312 in FIG. 3) of the LGAD device. Shallow p-type wells (p-well) 710 are formed in the deep p-wells 708 proximate an upper surface of the deep p-wells, such as by an implant process. N-type metal-oxide-semiconductor field-effect transistors (MOSFETs), and other circuit components (e.g., resistors, etc.), can be formed in the p-wells 710 in a conventional manner. The deep p-wells 708 may also include n-type wells (n-well) 712 formed therein, such as by an implant process. P-type MOSFETs, and other circuit components, can be formed in the n-wells 712 in a conventional manner.

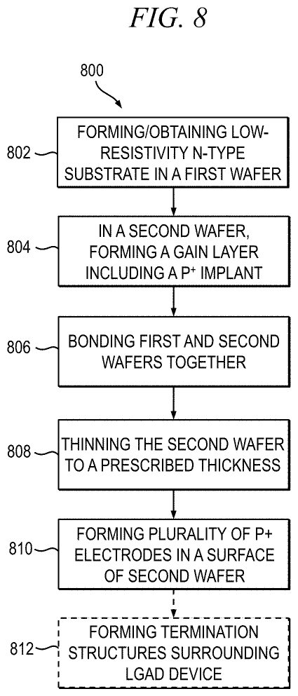

As previously described, embodiments of the invention beneficially provide a simplified method for fabricating an LGAD device having superior performance characteristics, such as, for example, uniform gain. FIG. 8 is a flow diagram depicting at least a portion of an exemplary method 800 for fabricating an LGAD device, according to an embodiment of the invention. With reference to FIG. 8, the method 800 involves forming or obtaining a first silicon wafer comprising a low-resistivity n-type (n⁺⁺) semiconductor substrate in step 802. In a second wafer, a p-type (p⁺) gain layer is formed in step 804, proximate an upper surface of the second wafer. The gain layer is formed in the second wafer, in one or more embodiments, using a p⁺ implant process, such as, for example, boron ion implantation.

In step 806, the first and second wafers are bonded or otherwise joined together using a known wafer bonding technique, such as, but not limited to, direct or fusion bonding, surface activated bonding (SAB), plasma-activated bonding, adhesive bonding, diffusion bonding, etc. The wafers are bonded by flipping the second wafer upside-down, such that the gain layer formed in the upper surface of the second wafer is in contact with the upper surface of the first wafer. After bonding, a back surface of the second wafer becomes an upper surface of the resulting bonded wafer structure. The second wafer is preferably thinned to a prescribed thickness in step 808 (e.g., about 20-50 μm), such as by performing back-grinding, polishing, etc., if needed. Next, in step 810 a plurality of p-type (p⁺⁺) electrodes are formed in the upper surface of the bonded wafer structure. As previously explained, these p⁺⁺ electrodes serve as the p-type hole-collecting electrodes of the enhanced LGAD device.

Optionally, termination structures are formed in step 812 surrounding the LGAD device. In one or more embodiments, the termination structures are formed as trenches, although embodiments of the invention are not limited to such an implementation. The termination structures serve to limit large currents that may develop at edges of the LGAD device, where the n-type wafer is in contact with the p-type wafer.

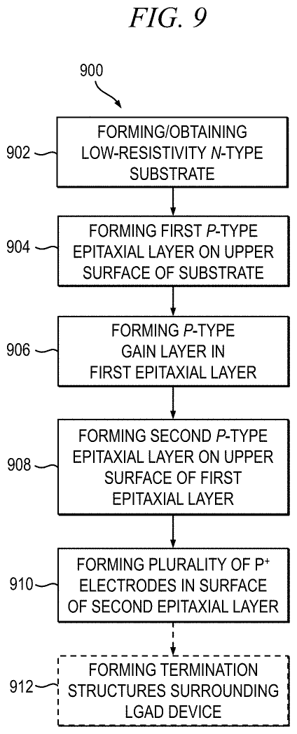

FIG. 9 is a flow diagram depicting at least a portion of an exemplary method 900 for fabricating an LGAD device which does not involve wafer bonding, according to an alternative embodiment of the invention. Consistent with step 802 in FIG. 8, the method 900 starts out by obtaining a silicon wafer comprising, or otherwise forming, a low-resistivity n-type (n⁺⁺) semiconductor substrate in step 902. Step 904 comprises depositing or growing a first p-type (but also n-type may work) thin (e.g., about 1-2 μm), high-resistivity (e.g., greater than about 100 ohm-cm) epitaxial layer on the n⁺⁺ substrate, and then performing an p⁺ implant process in step 906 to form a gain layer in an upper surface of the first epitaxial layer. Alternatively, the first epitaxial layer itself can be used as a gain layer. In this latter case, the resistivity of the first epitaxial layer is not so high and there is no need for performing the implant in step 906.

The alternative method 900 further includes forming a second p-type epitaxial layer in step 908 on the upper surface of the first epitaxial layer and over the gain layer. A cross-sectional thickness of the second epitaxial layer is preferably about 20-50 μm, as previously described in conjunction with the formation of the second epitaxial layer 308 shown in FIG. 3. Steps 910 and 912 are then performed in method 900 for forming p⁺ electrodes and optional termination structures, respectively, consistent with corresponding steps 810 and 812 in the illustrative method 800 shown in FIG. 8 and described above.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Any of the exemplary structures or circuits illustrated in the accompanying figures, or portions thereof, may be part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having power LGAD devices therein formed in accordance with one or more embodiments of the invention, such as, for example, silicon sensors, etc.

An integrated circuit in accordance with aspects of the present disclosure can be employed in essentially any silicon sensor application and/or electronic system, such as, but not limited to, low-energy particle detection systems, etc. Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “above,” “below,” “upper” and “lower” are used to indicate a position of elements or structures relative to one another, rather than absolute positioning.

The corresponding structures, materials, acts, and equivalents of all means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus, the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

What is claimed is:

1. A method for fabricating a low-gain avalanche diode (LGAD) device, the method comprising:
forming a low-resistivity n-type semiconductor substrate in a first silicon wafer;
forming a p-type gain layer in an upper surface of a high-resistivity p-type second silicon wafer;
bonding the first and second wafers such that the upper surface of the second wafer proximate the gain layer contacts the semiconductor substrate in the first wafer to form a bonded wafer structure, whereby a back surface of the second wafer becomes an upper surface of the bonded wafer structure;
forming a plurality of p-type electrodes in the upper surface of the bonded wafer structure; and
forming a conductive layer on at least a portion of the respective p-type electrodes and on a back surface of the semiconductor substrate, the conductive layer providing electrical connection to the LGAD device.

2. The method of claim 1 wherein the low-resistivity n-type semiconductor substrate has resistivity of less than about 0.1 ohm-cm.

3. The method of claim 1 wherein the low-resistivity n-type semiconductor substrate has a thickness that is a few nanometers to a few hundreds of microns thick.

4. The method of claim 1 wherein the low-resistivity n-type semiconductor substrate is formed of microcrystalline silicon modified with an n-type impurity or dopant.

5. The method of claim 1 wherein the high-resistivity p-type second silicon wafer has a resistivity at least 100 ohm-cm.

6. The method of claim 1 wherein the high-resistivity p-type second silicon wafer has a thickness of about 1-2 μm.

7. A method for fabricating a low-gain avalanche diode (LGAD) device, the method comprising:
obtaining a silicon wafer including a low-resistivity n-type semiconductor substrate;
forming a first epitaxial layer on at least a portion of an upper surface of the semiconductor substrate, the first epitaxial layer being of n-type or p-type conductivity;
forming a p-type gain layer in an upper surface of the first epitaxial layer, the gain layer being closely proximate the upper surface of the semiconductor substrate;
forming a second epitaxial layer on at least a portion of an upper surface of the first epitaxial layer and over the gain layer, the second epitaxial layer being p-type and having a cross-sectional thickness that is configured to achieve a prescribed speed performance in the LGAD device;
forming a plurality of p-type electrodes in an upper surface of the second p-type epitaxial layer; and
forming a conductive layer on at least a portion of the respective p-type electrodes and on a back surface of the semiconductor substrate, the conductive layer providing electrical connection to the LGAD device.

8. The method of claim 7 wherein the low-resistivity n-type semiconductor substrate has resistivity of less than about 0.1 ohm-cm or any resistivity.

9. The method of claim 7 wherein the low-resistivity n-type semiconductor substrate has a thickness that is a few nanometers to a few hundreds of microns.

10. The method of claim 7 wherein the low-resistivity n-type semiconductor substrate is formed of microcrystalline silicon modified with an n-type impurity or dopant.

11. The method of claim 7 wherein the p-type gain layer has a gain of about 10-100.

12. The method of claim 7 wherein the second epitaxial layer has a thickness of about 50 μm.
